(19) United States
(12) Patent Application Publication
(10) Pub. No.: US 2010/0149773 A1
(43) Pub. Date: Jun. 17, 2010

(54) INTEGRATED CIRCUIT PACKAGES HAVING SHARED DIE-TO-DIE CONTACTS AND METHODS TO MANUFACTURE THE SAME

(76) Inventor: Mohd Hanafi Mohd Said, Selangor (MY)

Correspondence Address: TEXAS INSTRUMENTS INCORPORATED, P O BOX 655474, M/S 3999, DALLAS, TX, 75265, US

(21) Appl. No.: 12/336,649

(22) Filed: Dec. 17, 2008

(51) Int. Cl. H01R 12/04; H01L 23/495; H01L 21/60

(52) U.S. Cl. 361/783; 257/676; 438/123; 257/E23.031; 257/E21.506

(57) ABSTRACT

Integrated circuit packages having shared die-to-die contacts and methods to fabricate the same are disclosed. A disclosed example integrated circuit package comprises a leadframe, a first die pad and a second die pad associated with the leadframe, and first and second integrated circuits associated with the first and second die pads, respectively. The package also includes a shared die-to-die contact externally exposed by a recess that extends laterally across a bottom surface of the leadframe between the first and second die pads. The first integrated circuit is electrically coupled to a first portion of the shared contact. The second integrated circuit is electrically coupled to a second portion of the shared contact.

### FIELD OF THE DISCLOSURE

This patent relates generally to semiconductor fabrication, and, more particularly, to integrated circuit packages having shared die-to-die contacts and methods of manufacturing the same.

### BACKGROUND OF THE DISCLOSURE

There are several known types of integrated circuit packages. For instance, a quad flat no-lead (QFN) package is a type of integrated circuit package that has contacts exposed on one or more peripheral edges of the package. Other types of integrated circuits include dual die, dual wire QFN packages, stacked die QFN packages, stacked die, multi-chip modules, ball grid array packages (BGAs), and Thin-Shrink Small Outline Packages (TSSOPs). In all of these package types, contacts or leads are positioned on the periphery of the package.

During fabrication using a QFN leadframe, a plurality of integrated circuits (also referred to as dies) are arranged in rows and columns on the leadframe. Each integrated circuit is typically located on a respective die pad via adhesive or the like, but multiple dies may be mounted to the same pad in some applications. The die pads, and, thus, the integrated circuits mounted thereon, are separated by two sets of streets. The streets are oriented in rows and columns (which are perpendicular to the rows) that together form a grid defining the die pads of the leadframe. Each of the streets includes a connecting bar. One can think of the connecting bars of the leadframe as comprising two halves—an upper, flange portion and a lower, base portion (also referred to as a spine). The adjacent contacts of a given die are electrically coupled via the spine of the connecting bar. Prior to singulation, each connecting bar electrically couples the contacts of a first die on one side of a street with the contacts of a second die on the opposite side of the street. Because the spine of each connecting bar also electrically couples adjacent contacts of the same die, the connecting bar is completely removed during the singulation stage of conventional fabrication processes to remove the short circuits between each adjacent pair of contacts of a single die and also to remove the short circuits between the contacts of adjacent dies.

Some known packages contain more than one integrated circuit. The integrated circuits (also commonly referred to as dies) may be stacked one upon the other or arranged in a side-by-side manner. The side-by-side layout can be formed in a single package such that pairs of die pads/dies are maintained within the same package. Irrespective of the layout of the dies, it is typically desirable for the integrated circuits to communicate within the package. As a result, the integrated circuits are often communicatively coupled by wires within the package. For example, a bond wire may be affixed at a first end to a pad of a first die and at an opposite end to a pad of a second die. Such a connection may be entirely internal to the package (i.e., the wire may be encapsulated within molding compound).

However, it is also frequently desired to communicate shared signals with components external to the package via an external contact of the package. In such circumstances, a first end of a first bond wire is affixed to the external contact at the edge of the package. A second end of the first bond wire is affixed to a pad of a first one of the integrated circuits. A first end of a second bond wire is also affixed to the external contact. A second end of the second bond wire is affixed to a pad of a second one of the dies. This approach enables communication of a signal to both dies via the external contact. Alternatively or additionally, this approach enables communication from one of the dies to the other of the dies and an external component via the external contact. A similar result can be achieved without directly connecting the first ends of the first and second bond wires to the external contact by connecting the first ends of the first and second bond wires to a post internal to the package, and connecting a third bond wire from the post to the external contact. In all of the above examples, the external contacts are located on the peripheral edge(s) of the package.

While the above approaches have made it possible to produce packages containing multiple dies that may be tested via the same external contact, the above approaches have required multiple steps during fabrication. Thus, it is desirable to provide an improved fabrication process for efficiently mass producing integrated circuit packages that permit testing of multiple dies via a same external contact.

### SUMMARY

This disclosure describes semiconductor packages containing first and second integrated circuits which are electrically coupled via a shared contact that is externally exposed for contact by components outside the package by a slot or recess extending laterally across the bottom surface of the package. The slot or recess is fabricated by removing a lower portion of a connecting bar (e.g., the spine of a QFN package) thereby separating and electrically isolating the adjacent contacts of the first integrated circuit from one another and the adjacent contacts of the second integrated circuit from one another without completely severing the connection bar and, thus, without physically separating or electrically isolating the first integrate circuit and the second integrated circuit at one or more contacts. Because the upper portion of the connecting bar forms the contacts of both the first and second integrated circuits, removal of the spine without removing the upper portion of the connecting bar forms a recess and creates externally exposed, die-to-die contacts. As a result of the complete removal of the spine, each contact of a given die is separated from the adjacent contacts of the same die, but remains connected to a respective contact in an adjacent die via the upper portion of the connecting bar to thereby form a die-to-die contact. (If desired, some of these die-to-die contacts can be broken by a further singulation process to enable creation of any number of die-to-die contacts and any number of single die contacts.) Because the lower portion of the connecting bar (e.g., the spine) can be easily removed with a singulation saw or the like, this fabrication methodology achieves improvements in the mass production of semiconductor packages having die-to-die, externally exposed contacts. Further, this fabrication methodology enables the creation of semiconductor packages having a die-to-die, externally exposed contact without requiring specially designed leadframes. On the contrary, it leverages existing QFN leadframe structure by modifying the fabrication process to remove the spine of a connecting bar while avoiding a complete through cut of a conductive block to thereby create an externally exposed, die-to-die contact.

### BRIEF DESCRIPTION OF THE DRAWINGS

FIG. 1 is perspective view of an example integrated circuit package containing two integrated circuits and one or more shared die-to-die contacts.

FIG. 2 is a cross-sectional view of the example integrated circuit package taken along line 2-2 of FIG. 1.

FIG. 3 is a cross-sectional view of an example electronic device constructed using the example integrated circuit package of FIG. 1.

FIG. 4 is a flowchart illustrating an example fabrication process that may be carried out to form the example integrated circuit package of FIGS. 1 and 2.

FIGS. 5A-5E illustrate an example integrated circuit package at various stages of the example fabrication process of FIG. 4.

For ease of illustration and understanding, the thicknesses of the layers are enlarged in the drawings. Wherever possible, the same reference numbers will be used throughout the drawing(s) and accompanying written description to refer to the same or like parts. As used in this patent, stating that any part (e.g., a solder ball, a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

In some integrated circuit packages, two or more integrated circuits (e.g., processor cores, digital signal processing cores, memory devices, etc.) are packaged together to, for example, permit parallelization of operation, improve performance, etc. In such packages, it may be preferable to test each of the integrated circuits at substantially the same time. However, the simultaneous testing of separate integrated circuits in the same package has been difficult. To overcome this or other problems, the example packaged integrated circuits described herein include two or more integrated circuits that are electrically coupled to an externally exposed shared contact exposed via a slot, recess or trench formed in a bottom surface of the package. The externally exposed shared contact allows for die-to-die signals to be monitored or controlled external to the packaged integrated circuit. As described herein, such packages can be mass produced more efficiently than conventional packages and without the need for die-to-die bond wires, without the need for specially designed leadframes, and with integrated circuits having small or soft bond pads that may not tolerate the placement of multiple bond wires. Although the disclosed example methods and apparatus leverage the structure of a Quad flat no-lead (QFN) leadframe to achieve these advantages and, thus, will be described herein in the context of such a package, this disclosure is not limited to QFN packages. On the contrary, the teachings of this disclosure may be applied to other types of integrated circuit packages. Moreover, while two integrated circuits are shown in the examples described herein, the disclosed examples and methods can be used to construct a packaged integrated circuit having any number of integrated circuits contained therein.

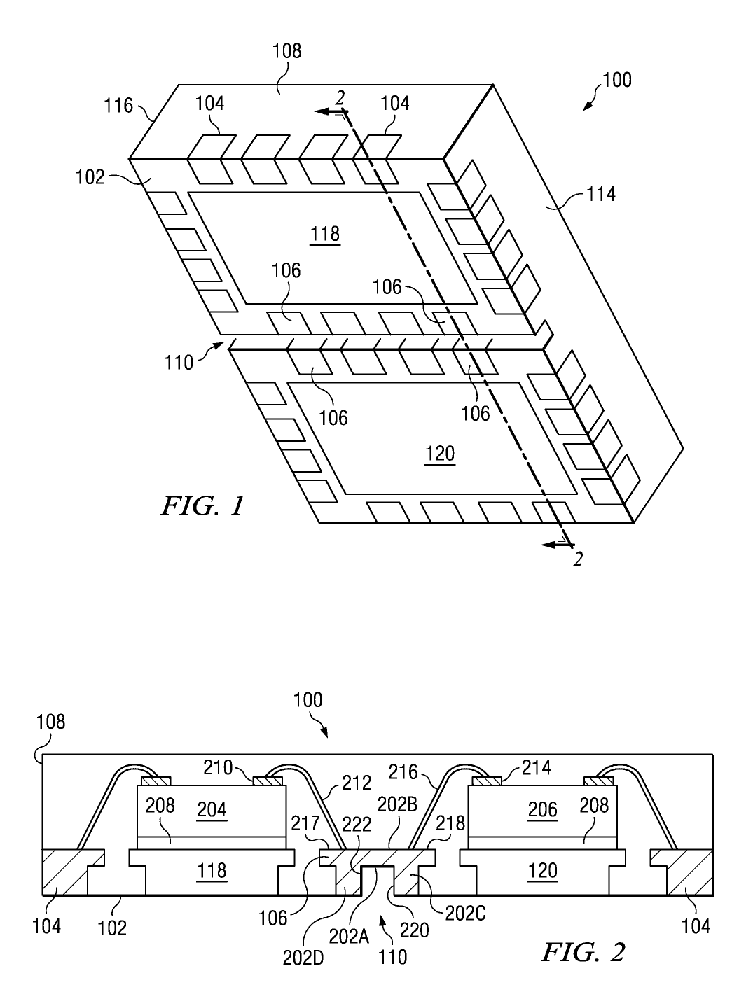

FIG. 1 is a bottom, perspective view of an example packaged integrated circuit 100 constructed in accordance with the teachings of the disclosure. FIG. 2 is a cross-sectional view of the example packaged integrated circuit 100 taken along line 2-2 of FIG. 1. The example integrated circuit package 100 of FIG. 1 is a QFN package having two integrated circuits 204 and 206 (See FIG. 2) contained therein. The example QFN package 100 of FIG. 1 is a near chip-scale package. In particular, the total surface area of the bottom surface 102 of the integrated circuit package 100 is only slightly larger (e.g., 25% larger) than the collective bottom surface areas of the integrated circuits 204 and 206 contained therein. A QFN package typically has a thickness between its top and bottom surfaces of approximately 0.4 millimeters (mm) to approximately 0.9 mm, a die pad thickness of approximately 0.4 mm to approximately 0.8 mm, and an integrated circuit thickness of approximately 0.2 mm to approximately 0.4 mm.

To allow the example integrated circuit package 100 of FIG. 1 to be electrically or mechanically coupled to, for example, a circuit board, the example integrated circuit package 100 includes a plurality of peripheral contacts 104 and a plurality of trench exposed contacts 106. Both the peripheral contacts 104 and the trench exposed contacts 106 are exposed on the bottom surface 102 of the package 100. As shown in FIG. 1, the peripheral contacts 104 and the trench exposed contacts 106 are also exposed on other surfaces of the package 100. For example, the peripheral contacts 104 are also exposed on a side surface 108 of the example package 100, and the example trench exposed contacts 106 are also exposed on the sides of a recess or slot 110 defined in the bottom 102 of the package 100. The example trench exposed contacts 106 of FIG. 1 are die-to-die contacts shared by both of the integrated circuits 204 and 206 (See FIG. 2) of the example package 100. The integrated circuits 204 and 206 can communicate or pass signals via the shared die-to-die contacts 106. The example die-to-die contacts 106 are exposed on the bottom surface 102 adjacent the recess or slot 110, and along the intervening three sides of the recess or slot 110. The surfaces of the example package 100 (e.g., the surfaces 102, 108 and the sides of the recess or slot 110) are formed from a molding compound used to encapsulate the integrated circuits and their associated bond wires.

The example slot or recess 110 of FIG. 2 extends laterally through the shared die-to-die contacts 106. The die-to-die contacts 106 are exposed on a bottom surface 202A of slot 110. In the illustrated example of FIG. 1, the recess 110 extends from a third surface 114 of the package 100 to a fourth surface 116 of the package opposite the third surface 114. In particular, the trench 110 bisects the package into a first portion containing the first integrated circuit 204 and a second portion containing the second integrated circuit 206 without physically splitting the package 100 into two separate pieces. Although all of the contacts along the slot 110 are shown as die-to-die contacts, some of the contacts may not be die-to-die contacts, but instead may be formed as single die contacts by completing the singulation of their respective conductive blocks (e.g., by sawing the conductive block completely in half).

As shown in FIG. 2, an example shared die-to-die contact 106 has a π (pi) shaped cross section. A top surface 202B of the shared die-to-die contact 106 provides a bonding surface for communicatively coupling bond wires to the contact 106. The legs 202C and 202D of the shared die-to-die contact 106 are separated by a distance corresponding to the slot 110. The opposed surfaces 220 and 222 of the legs 202C and 202D are exposed within the slot 110. Although in the illustrated example, the shared die-to-die contact 106 has a π shaped cross-section, other shapes are likewise appropriate. For example, inverted U shaped cross sections, or n shaped cross sections could likewise be employed.

FIG. 2 is a cross-sectional view of the example package 100 taken along line 2-2 of FIG. 1. As shown in FIG. 2, the example package 100 includes two die pads 118 and 120. The die pads 118 and 120 are exposed on the bottom surface 102 of the package 100. The first integrated circuit 204 is attached, affixed or adhered to the first die pad 118, and the second integrated circuit 206 is attached, affixed or adhered to the second die pad 120. The example integrated circuits 204 and 206 are attached to their respective die pads 118 and 120 via an adhesive 208 (e.g., an epoxy, a polyimide film, etc.). The example integrated circuit 204 includes one or more pads (one of which is designated at reference numeral 210) that are electrically coupled to one or more conductive blocks or contacts 104, 106 of the package 100 via one or more corresponding bond wires (one of which is designated at reference numeral 212). Likewise, the example integrated circuit 206 includes one or more pads (one of which is designated at reference numeral 214) that are electrically coupled to one or more conductive blocks or contacts 104, 106 of the package 100 via one or more corresponding bond wires (one of which is designated at reference numeral 216).

In the example package 100 of FIG. 2, the pad 210 of the first integrated circuit 204 is to be electrically coupled to the pad 214 of the second integrated circuit 206. To this end, the pad 210 is electrically coupled via a bond wire 212 to a first end or portion 217 of the top surface 202B of the shared die-to-die contact 106. To complete the electrical coupling of the pad 210 to the pad 214, the example pad 214 is electrically coupled via a second bond wire 216 to an opposite end or portion 218 of the top surface 202B of the shared die-to-die contact 106. As shown in FIG. 2, the pads 210 and 214 are electrically coupled via the shared die-to-die contact 106 without the need for double bonding on either of the pads 210 or 214. Because the shared die-to-die contact 106 of FIGS. 1 and 2 is exposed on one or more surfaces 202A, 220 and 222, the signal(s) shared by the integrated circuits 204 and 206 can be monitored, accessed or controlled via the shared die-to-die contact 106 by, for example, devices of a circuit board to which the package 100 is attached. As shown in the illustrated example of FIG. 2, other pads of the integrated circuits 204 and 206 can be electrically coupled to, for example, other devices or components of a circuit board, via shared or non-shared contacts and respective bond wires.

In contrast to traditional multi-die packages, the example package 100 of FIG. 2 provides external exposure of one or more signals that are shared between the integrated circuits 204 and 206, and allows for the use of shorter bonds wires 212 and 216 between the integrated circuits 204, 206, thereby reducing bond wire inductances. Moreover, the use of stand-off-stitch bonds or stitch-on-bump bonds is eliminated, thereby improving both moisture sensitivity level performance and manufacturability. Furthermore, because of the exposed shared contacts 106, the example integrated circuits 204 and 206 can be tested either individually or in combination. Further still, other external devices can monitor the signals exchanged between the integrated circuits 204 and 206, thereby allowing the external devices to further control or improve the operation of the integrated circuits 204 and 206. Further yet, the shared die-to-die contact(s) 106 can be used to electrically couple both of the integrated circuits 204 and 206 to a common signal such as a ground signal or a voltage supply signal.

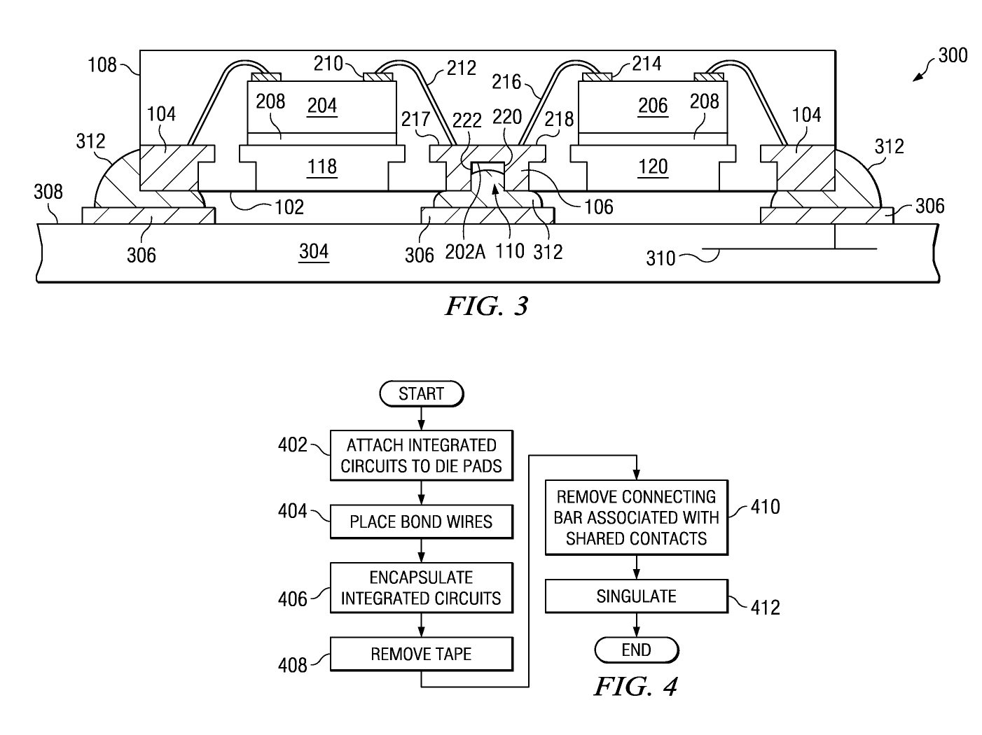

FIG. 3 is a cross-sectional view of an example electronic device 300 constructed by attaching, among other things, the example package 100 of FIGS. 1 and 2 to a circuit board 304. The example circuit board 304 of FIG. 3 has a plurality of electrically conductive pads (one of which is designated at reference numeral 306) on a surface 308 of the circuit board 304. The example pads 306 of FIG. 3 may be coupled to other devices or components of the circuit board 304, or to a component or device which is electrically coupled to the circuit board 304, via one or more signal traces or vias of the circuit board 304 (one of which is designated at reference numeral 310).

Each of the example contacts 104 and 106 of the package 100 is electrically coupled to a corresponding pad 306 via solder 312. In the illustrated example of FIG.3, the solder 312 establishes an electrical coupling between the circuit board 204 and both of the integrated circuits 204 and 206 via the shared die-to-die contact 106.

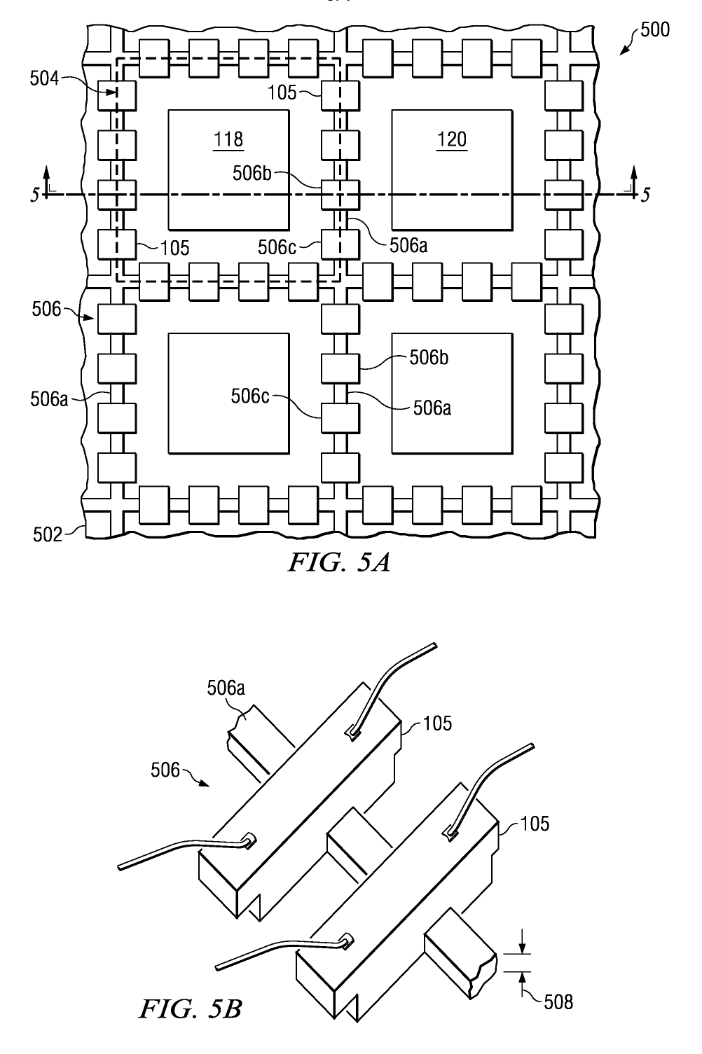

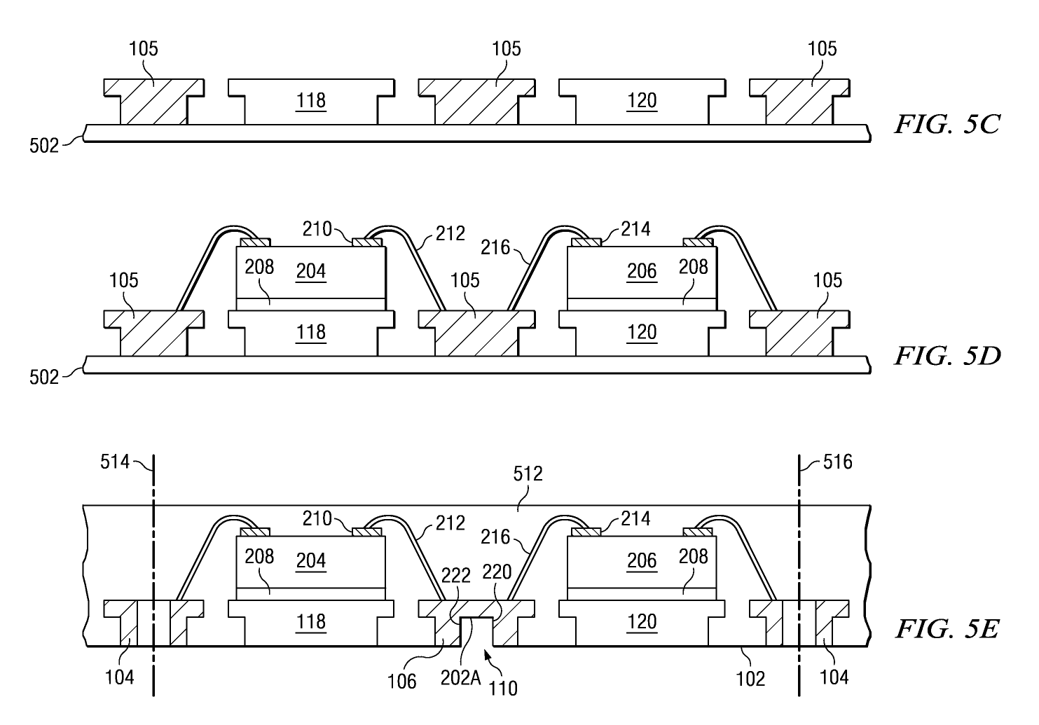

FIG. 4 is a flowchart illustrating an example manufacturing process that may be carried out to fabricate the package 100 of FIG. 1. The example process of FIG. 4 will be explained in conjunction with FIGS. 5A-5E, which illustrate the example package 100 of FIGS. 1 and 2 at different stages of fabrication. The example process of FIG. 4 may be carried out by one or more pieces of manufacturing equipment, one or more processors, one or more controllers or any other suitable processing devices. For example, the example process of FIG. 4 may be embodied in coded instructions stored on a tangible medium such as a flash memory, a read-only memory (ROM), a random-access memory (RAM) or any combination thereof associated with a processor. Alternatively, some or all of the example process of FIG. 4 may be implemented using any combination(s) of hardware or firmware or software. Also, some or all of the example process of FIG. 4 may be implemented manually or as any combination of any of the foregoing techniques, for example, any combination of firmware, or software, or discrete logic or hardware. Further, many other methods of implementing the example process of FIG. 4 may be employed. For example, the order of execution of the blocks may be changed, or one or more of the blocks described may be changed, eliminated, sub-divided, or combined. Moreover, while the example process of FIG. 4 is described relative to a single package 100, the process of FIG. 4 may be, additionally or alternatively, carried out to simultaneously fabricate a plurality of packages.

The example process of FIG. 4 begins with a leadframe such as the example QFN leadframe 500 of FIG. 5A. The example leadframe 500 of FIG. 5A is attached to a tape 502 (FIG. 5C). The example leadframe 500 includes a plurality of cells or frames, one of which is designated at reference numeral 504 in FIG. 5A. The example frames 504 of FIG. 5A are arranged in a matrix suitable for the high-volume packaging of integrated circuits. Each of the example frames 504 includes a respective die pad 118, 120 and a set of associated conductive blocks 105. As shown in more detail in FIG. 5B, the conductive blocks 105 are integrally formed as a connecting bar 506. The lower portion 506a of the connecting bar 506 is, in this example, the spine of a QFN connecting bar and, thus, it electrically couples the contacts of the dies prior to singulation. As discussed below, by removing the lower portion 506a of the connecting bar 506 (e.g., via etching or sawing via a singulation saw), the conductive block 105 is turned into a die-to die contact 106 and, at the same time, is electrically isolated from adjacent conductive blocks/contacts. Thus, the height 508 of the lower portion 506a of the connecting bar 506 substantially corresponds to the final height of the example recess 110 of FIG. 2. FIG. 5C illustrates a cross-sectional view of the example leadframe 500 taken along line 5-5 of FIG. 5A.

As noted above, removing the spine 506a separates adjacent conductive blocks 506. For example, as shown in FIG. 5A, removal of the spine 506a will break the connection between conductive blocks 506b and 506c. However, because the singulation process does not completely sever the conductive blocks 506, 506b, 506c, die-to-die contacts are maintained between adjacent dies. Thus, removal of the spine 506a enables creation of die-to-die contacts while eliminating short circuits between the contacts within a given die.

As shown in FIG. 5D, the example process of FIG. 4 attaches the dies 204 and 206 to their respective die pads 118 and 120 using adhesive 208 (block 402). Bond wires 212 and 216 are placed between the pads 210 and 214 of the integrated circuits 204 and 206 and corresponding conductive blocks 105 (block 404).

As shown in FIG. 5E, the conductive blocks 105, the die pads 118 and 120, the bond wires 212, 216, and the integrated circuits 204 and 206 are then encapsulated in a molding material 512 (block 406). After the molding material 512 solidifies, the tape 502 may be removed (block 408). In some examples, no tape 502 is employed. The example encapsulant (i.e., molding material) 512 of FIG. 5E is formed to have a bottom surface 102 that is flush with the bottoms of the contacts 104 and 106 and the die pads 118 and 120. In some examples, the molding material 508 is originally formed to fully encapsulate the contacts 104 and 106 and the die pads 118 and 120, and then a portion of the molding material 512 is removed (e.g., by etching or milling) to form a bottom surface 102 that is flush with the bottoms of the contacts 104 and 106 and the die pads 118 and 120.

The lower portions 506a of the connecting bars 506 (e.g., the spines) associated with the shared die-to-die contacts 106 are removed using, for example, a singulating saw, an etching process, etc., to form the recess or slots 110 of the packages (block 410). As shown in FIG. 5E, removing the lower portions 506a of the connecting bar 506 exposes surfaces 202A, 220 and 222 of the shared contact 106 while keeping the two halves of the shared die-to-die contact 106 electrically connected. A singulating saw makes through cuts along the connecting bars 506 associated with the peripheral contacts 104 (e.g., along lines 514 and 516 of FIG. 5E) to split the leadframe into a plurality of packages such as the example package 100 of FIGS. 1 and 2 (block 412). For example, as illustrated in FIG. 5E, by cutting along line 514, the conductive block 105 is split into two peripheral contacts 104 on separate packages 100. Each peripheral contact 104 is exposed on both the bottom surface 102 and a side surface 108 (e.g., along the cut) of its corresponding package 100.

It is not necessary for all the conductive blocks 105 along the slot to be formed into die-to-die contacts. Instead, one or more of the conductive blocks may be formed into single die contacts. Such single die contacts may be formed by, for example, selectively dividing one or more of the conductive blocks 105 into separate, electrically isolated (single die) contacts for separate dies. For example, such contacts could be formed by increasing the depth of the singulation cut for those particular conductive blocks 105 that are to be formed into single die contacts without cutting all the way through those conductive blocks 105 that are to serve as die-to-die contacts, an etching process and/or a laser ablation process.

Although certain methods, systems, and articles of manufacture have been described herein, the scope of coverage of this patent is not limited thereto. To the contrary, this patent covers all methods, systems, and articles of manufacture fairly falling within the scope of the appended claims either literally or under the doctrine of equivalents.

What is claimed is:

1. An integrated circuit package comprising:
a leadframe;
a first die pad and a second die pad associated with the leadframe;
first and second integrated circuits associated with the first and second die pads, respectively; and
a shared die-to-die contact externally exposed by a recess that extends laterally across a bottom surface of the leadframe between the first and second die pads, the first integrated circuit being electrically coupled to a first portion of the shared contact, and the second integrated circuit being electrically coupled to a second portion of the shared contact.

2. The integrated circuit package as defined in claim 1, wherein the first integrated circuit is electrically coupled to the first portion by a bond wire electrically coupled between the first portion of the shared contact and a pad of the first integrated circuit.

3. The integrated circuit package as defined in claim 1, further comprising:
a second contact exposed on a first edge of the integrated circuit chip, the first integrated circuit being electrically coupled to the second contact; and
a third contact exposed on a second edge of the integrated circuit chip, the second integrated circuit being electrically coupled to the third contact.

4. The integrated circuit package as defined in claim 1, wherein the shared die-to-die contact has a π shaped cross section.

5. The integrated circuit package as defined in claim 1, wherein the recess has at least one of a π shaped, an inverted U shaped, or an n shaped cross section.

6. The integrated circuit package as defined in claim 1, wherein the recess is located in a space formerly filled by a lower portion of a connecting bar of a leadframe.

7. A method to fabricate an integrated circuit package having first and second integrated circuits, the method comprising:
attaching the first integrated circuit to a first die pad of a first leadframe cell;
attaching the second integrated circuit to a second die pad of a second leadframe cell, the second leadframe cell being adjacent to the first leadframe cell on opposite sides of a connecting bar;
electrically coupling the first integrated circuit to a conductive block, the conductive block being located between the first and second leadframe cells;
electrically coupling the second integrated circuit to the conductive block;
encapsulating the first and second integrated circuits in a molding compound; and
removing a spine of the connecting bar to expose a first surface of the conductive block to form an external contact.

8. The method as defined in claim 7, wherein removing the spine defines a slot across a bottom surface of the package.

9. The method as defined in claim 8, wherein the slot laterally bisects the bottom surface of the integrated circuit chip.

10. The method as defined in claim 7, further comprising:
electrically coupling the first integrated circuit to a second conductive block; and
exposing a surface of the second conductive block to form a second external contact.

11. The method as defined in claim 7, wherein electrically coupling the first integrated circuit to the conductive block comprises placing a bond wire between a pad of the first integrated circuit and a pad of the conductive block.

12. The method as defined in claim 7, wherein the first integrated circuit is coupled to a first end of the conductive block and the second integrated circuit is coupled to a second end of the conductive block opposite the first end.

13. An electronic circuit comprising:
a circuit board; and
an integrated circuit package mounted on the circuit board, the package comprising:
a contact electrically coupled to the circuit board, the contact having a cross-section, the cross-section having at least one of a π shape, an inverted U shape, or an n shape, an inner portion of the π shape, the inverted U shape, or the n shape being externally exposed on a first surface of the integrated circuit package and
first and second integrated circuits encapsulated in a molding compound, the first and second integrated circuits being electrically coupled to the contact.

14. The electronic circuit as defined in claim 13, wherein the integrated circuit package further comprises:
a second contact electrically coupled to the circuit board and exposed on a second surface of the integrated circuit chip, the first integrated circuit being electrically coupled to the second contact; and
a third contact electrically coupled to the circuit board and exposed on a third surface of the integrated circuit chip, the second integrated circuit being electrically coupled to the third contact.

15. The electronic circuit as defined in claim 13, wherein the first surface of the integrated circuit package comprises a bottom of the package.

16. The electronic circuit as defined in claim 13, wherein the first surface of the integrated circuit package is bisected by a recess.

17. The electronic circuit as defined in claim 16, wherein the inner portion of the contact straddles the recess.

18. The electronic circuit as defined in claim 16, wherein the inner portion of the contact at least partially defines the recess.
